(19) United States
(12) Patent Application Publication
(10) Pub. No.: US 2012/0127005 A1
(43) Pub. Date: May 24, 2012

(54) FAST QUANTIZER APPARATUS AND METHOD

(75) Inventors: Jeongseok Chae, Goyan-city (KR); Gabor C. Temes, Corvallis, OR (US)

(73) Assignee: ASAHI KASEI MICRODEVICES CORPORATION, Tokyo (JP)

(21) Appl. No.: 13/298,352

(22) Filed: Nov. 17, 2011

Related U.S. Application Data
(60) Provisional application No. 61/415,041, filed on Nov. 18, 2010.

(51) Int. Cl. H03M 1/06; H03M 99/00

(52) U.S. Cl. 341/118; 341/200

(57) ABSTRACT

An apparatus and method for a fast quantizer comparator comprising three stages: a preamplifier stage, a regeneration latch stage, and a data latch stage. Time delay is reduced by changing the initial voltages of the regeneration latch outputs. The current source is provided at the tail of the comparator, enabling time delay optimization. When the PMOS equalization switch turns off, it makes the clock signal feedthrough and provides charge injection into the outputs. Because of these charges, the time delay of the comparator is variable. Only a very low current sets the output voltages because the resetting time is longer than the comparison time.

### RELATED APPLICATIONS

This application claims the benefit of U.S. Provisional Application No. 61/415,041 filed Nov. 18, 2010; this application is herein incorporated in its entirety by reference.

### FIELD OF THE INVENTION

The invention relates to architectures for low-distortion delta sigma modulators, particularly to a fast quantizer and method providing optimized time delay.

### BACKGROUND OF THE INVENTION

A wide range of products incorporate high speed circuits that form analog to digital converters (ADCs) and digital to analog converters (DACs). These include delta-sigma (ΔΣ) modulators. Performance expectations of these products are constantly driving designs to achieve greater linearity and bandwidth while limiting or reducing power consumption. The field of signal processing generally is demanding enhanced specifications. These demands involve conflicting attributes such as size, cost, complexity, power, speed, signal bandwidth, noise and stability. Products demanding this increased performance include data and signal transceivers in audio, video, and RF applications.

Approaches to improving the performance of modulators have included employing high order, low-distortion architectures. This involves an increased number of adder inputs and increased coefficients. While increased adder inputs can obtain more effective feedback, instability can also increase. Instability can result from circuit delays, especially loop delay.

FIG. 1 is a block diagram 100 of a known third-order modulator including a quantizer 155. As mentioned, as the number of adder inputs and coefficients are increased, the adder feedback factor β becomes lower, hence high power consumption to get wide bandwidth or good phase margin. In the circuit of FIG. 1, input U 110 is applied to summing nodes 105 and 115. Output of summing node 115 is applied to input of integrator 120. Output of integrator 120 is applied to input of feedforward path 125 and input of summing node 130. Output of summing node 130 is applied to input of integrator 135. Output of integrator 135 is applied to input of feedforward path 140 and input of integrator 145. Output of integrator 145 is applied to input of feedback path 150, whose output is applied to summing node 130. Output of integrator 145 is also applied to summing node 105, whose output is applied to quantizer 155. Quantizer output is returned to summing node 115 by digital output feedback path with DAC 160 and also provides output V 165.

What is needed are techniques for providing low distortion and wide bandwidth while maintaining stability without increasing power consumption.

### SUMMARY OF THE INVENTION

Embodiments provide a low-distortion architecture with reduced loop delay to control stability. Double sampling, quantization and dynamic element matching (DEM) are accomplished within non-overlap time. By reducing the time delay, power can be saved for analog integrators.

One embodiment of the present invention is a fast quantizer comparator device for optimizing delay time comprising at least a first stage preamplifier; at least a second stage regeneration latch, comprising a current source at the tail of the regeneration latch; and at least a third stage data latch, wherein time delay is reduced and optimized through initial voltages provided by the preamplifier stage to regeneration latch outputs of the regeneration latch stage.

Another embodiment is a method for a fast quantizer comparator for optimizing modulator loop delay time, the method comprising the steps of: turning off a PMOS equalization switch; feeding through a clock signal from the turning off of the PMOS equalization switch; and injecting charge into at least regeneration latch output A and regeneration latch output B from the turning off of the PMOS equalization switch, whereby time delay is varied based on the charge injection into the at least regeneration latch output A and the regeneration latch output B.

Embodiments (as in FIG. 2) include a fast quantizer comparator device (200) for optimizing delay time comprising at least a regeneration latch (210), comprising an equalization switch (245) between a first regeneration latch output (A 255) and a second regeneration latch output (B 260), and a current source (280) at the tail of the regeneration latch (210) wherein the equalization switch (245) turns on during the resetting time. For other embodiments, the current source (280) provides low DC current. In another embodiment, the regeneration latch comprises a comparison switch (250) at the tail of the regeneration latch (210), wherein the comparison switch (250) turns on during the comparison time. Yet another embodiment further comprises at least a preamplifier (205) connected ahead of the regeneration latch; and at least a data latch (215) connected following the regeneration latch. For further embodiments, time delay is reduced and optimized through initial voltages provided by the preamplifier stage to regeneration latch outputs of the regeneration latch stage.

Subsequent embodiments provide a method for a fast quantizer comparator for optimizing modulator loop delay time, the method comprising the steps of biasing outputs of regeneration latch (210) with DC current; turning off equalization switch (245); feeding through the clock signal from the turning off of the equalization switch; and injecting charge into at least a first regeneration latch output (A) and a second regeneration latch output (B) from the turning off of the equalization switch, whereby time delay is varied based on the charge injection into at least the first regeneration latch output (A) and the second regeneration latch output (B).

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a block diagram of a known third-order modulator including a quantizer.

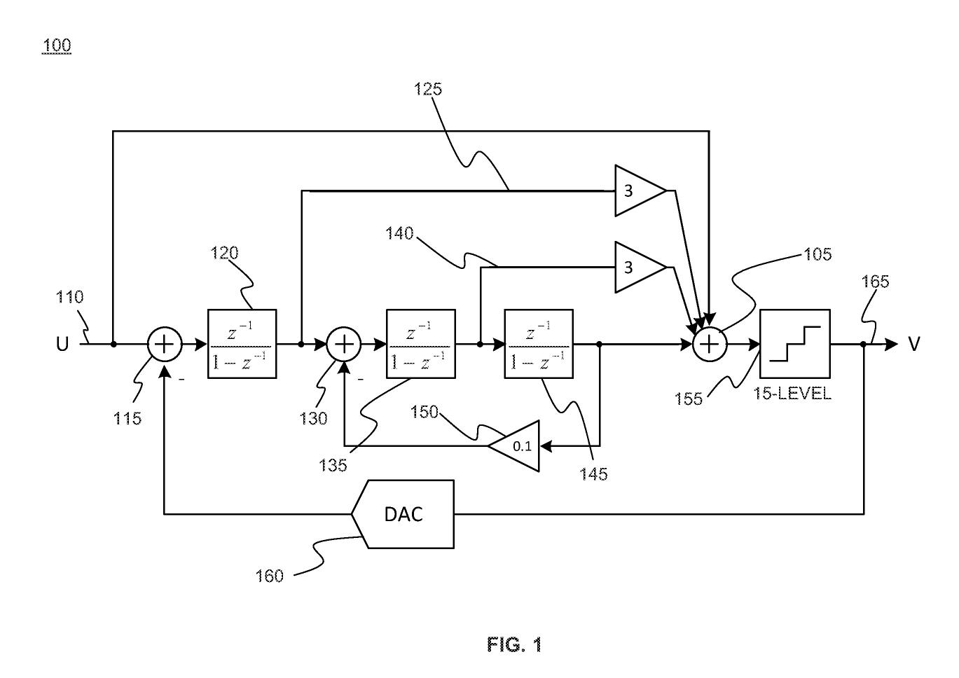

FIG. 2 is a circuit diagram illustrating a fast quantizer comparator configured in accordance with one embodiment of the present invention.

FIG. 3 is a flow chart depicting a fast quantizer comparator method configured in accordance with one embodiment of the present invention.

### DETAILED DESCRIPTION

The following detailed description provides example embodiments of the presently claimed invention with references to the accompanying drawings. The description is intended to be illustrative and not limiting the scope of the present invention. Embodiments are described in sufficient detail to enable one of ordinary skill in the art to practice the subject invention. Other embodiments may be practiced with some variations without departing from the spirit or scope of the subject invention.

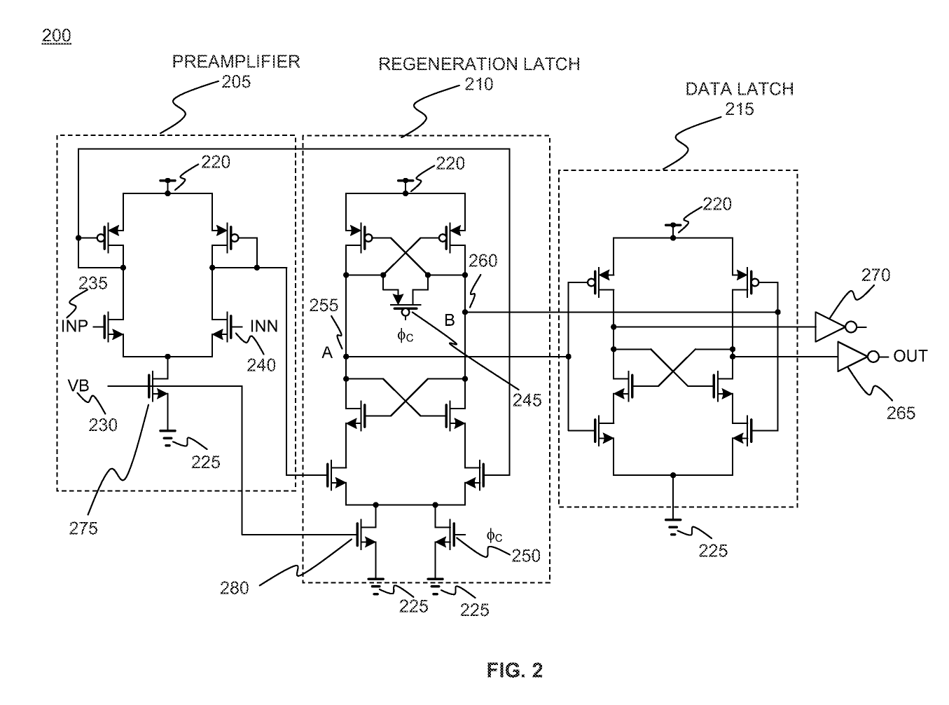

FIG. 2 depicts a fast quantizer comparator circuit embodiment 200. The circuit comprises three stages: a first preamplifier stage 205, a second regeneration latch stage 210, and a third data latch stage 215. Connections comprise VDD supply connections 220 and ground connections 225. Inputs comprise VB 230, INP 235, and INN 240. Switches comprise φc switches 245 and 250. Outputs comprise regeneration latch output A 255 and regeneration latch output B 260, OUT 265, and 270.

The second regeneration latch stage 210 comprises the PMOS equalization switch 245 between regeneration latch output A 255 and regeneration latch output B 260. The second regeneration latch stage 210 comprises the NMOS comparison switch 250 at the tail of the comparator regeneration latch 210, connecting to ground. The PMOS equalization switch 245 and the NMOS comparison switch 250 are alternately turned on or off.

The first preamplifier stage 205 comprises transistor 275 as a current source.

In embodiments, the second regeneration latch stage 210 comprises a transistor 280 as a current source. Because the current source 280 is at the tail of the comparator regeneration latch 210, time delay can be optimized.

A first phase is comparison time, when signal (φc=“H”. A second phase is resetting time, when signal (φc=“L”.

The PMOS equalization switch 245, when turned off (when the NMOS comparison switch 250 is turned on) injects charge into regeneration latch output A 255 and regeneration latch output B 260 in the first phase. Then, the PMOS equalization switch 245, when turned on (when the NMOS comparison switch 250 is turned off) resets the voltages of output A and output B in the second phase. The reset voltages of output A and output B can make change of latched value. Since the equalization voltages of output A and output B are equal to the logic threshold of the regeneration latch when the PMOS equalization switch 245 is on, the effect of injected charge can be reduced.

The current source 280 at the tail of the comparator regeneration latch 210 can provide a low DC Current, when the NMOS comparison switch 250 turned off, in the second phase. Only a low DC current is needed to set the voltages of output A 255 and output B 260 because their resetting time is longer than the comparison time.

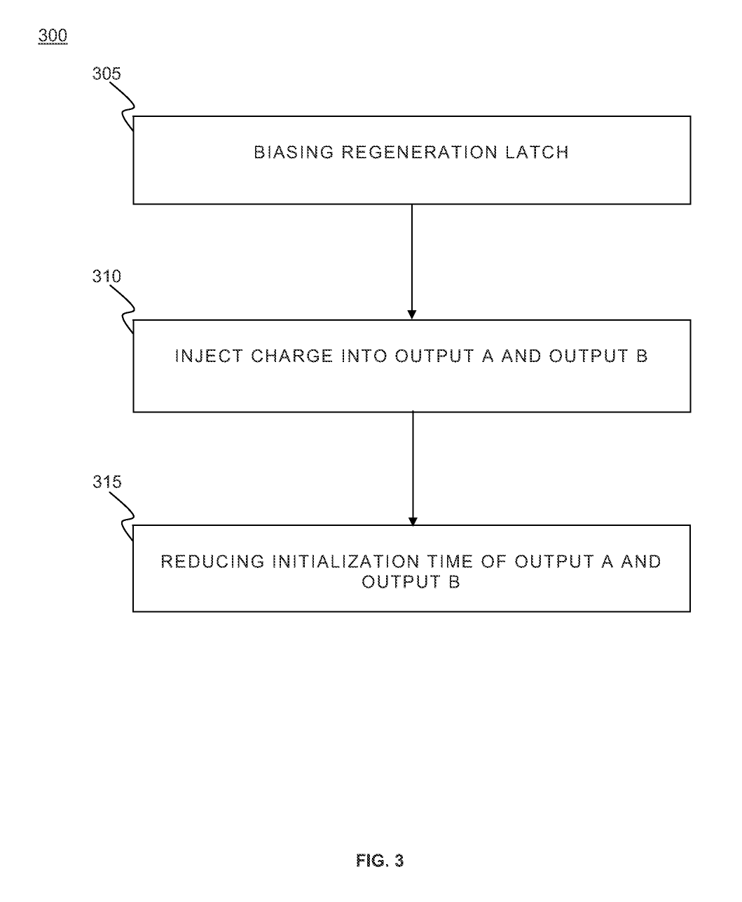

FIG. 3 is a flow chart 300 depicting an embodiment of a fast quantizer method. The method steps comprise biasing regeneration latch 305, charge injection into output A and output B 310, and reducing initialization time of output A and output B 315. The time delay is reduced by changing the initial voltages of the regeneration latch outputs (A and B), and hence the delay of the proposed comparator can be optimized. Because the resetting time is longer than the comparison time, only a very low direct current (DC) is needed to set the voltages of A and B.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure.

We claim:

1. A fast quantizer comparator device for optimizing delay time comprising:
at least a regeneration latch, comprising
an equalization switch between
a first regeneration latch output and
a second regeneration latch output, and
a current source at tail of said regeneration latch wherein said equalization switch turns on during the resetting time.

2. The fast quantizer comparator device of claim 1: said current source provides low DC current.

3. The fast quantizer comparator device of claim 1: said regeneration latch comprises a comparison switch at tail of said regeneration latch, wherein said comparison switch turns on during the comparison time.

4. The fast quantizer comparator device of claim 1 further comprising:
at least a preamplifier connected ahead of said regeneration latch; and
at least a data latch connected following said regeneration latch.

5. The fast quantizer comparator device of claim 4, wherein time delay is reduced and optimized through initial voltages provided by said preamplifier stage to regeneration latch outputs of said regeneration latch stage.

6. A method for a fast quantizer comparator for optimizing modulator loop delay time, said method comprising the steps of:
biasing outputs of regeneration latch with DC current;
turning off equalization switch;
feeding through clock signal from said turning off of said equalization switch; and
injecting charge into at least a first regeneration latch output and a second regeneration latch output from said turning off of said equalization switch, whereby time delay is varied based on said charge injection into said at least said first regeneration latch output and said second regeneration latch output.
